(19) United States
(12) Patent Application Publication
(10) Pub. No.: US 2026/0005203 A1
(43) Pub. Date: Jan. 1, 2026

(54) DISPLAY MODULE AND DISPLAY DEVICE

(71) Applicant: Tianma Advanced Display Technology Institute (Xiamen) Co.,Ltd., Xiamen (CN)

(72) Inventor: Yunyuan ZHANG, Xiamen (CN)

(21) Appl. No.: 18/830,164

(22) Filed: Sep. 10, 2024

(30) Foreign Application Priority Data
Jun. 28, 2024 (CN) 202410866325.1

(51) Int. Cl. H01L 25/075

(52) U.S. Cl. CPC H01L 25/0753

(57) ABSTRACT

The present disclosure provides a display module and a display device. The display module includes at least one display panel. The display panel includes a substrate, a light-emitting functional layer, a light transmission-covering layer, and an auxiliary structure. The light-emitting functional layer is disposed on one side of the substrate. The light transmission-covering layer is disposed on a side of the light-emitting functional layer away from the substrate. The auxiliary structure is disposed at an edge of the light transmission-covering layer.

### CROSS-REFERENCE TO RELATED APPLICATION

The present disclosure claims priority of Chinese Patent Application No. 202410866325.1, filed on Jun. 28, 2024, the entire content of which is hereby incorporated by reference.

### FIELD OF THE DISCLOSURE

The present disclosure generally relates to the field of display technology and, more particularly, relates to a display module and a display device.

### BACKGROUND

With the continuous development of display technology, the manufacturing technique of display screens has become increasingly mature, and large-size screens are widely used in various indoor and outdoor occasions. Large-size spliced display screens have replaced traditional large-size display screens and are favored by more and more users due to their portability, low failure rate, long life, and low power consumption, among other benefits and advantages. However, in existing spliced display screens, there are splicing gaps when adjacent display panels are spliced. When a spliced display screen displays images, the brightness at a splicing gap is relatively high, which affects the display performance of the spliced display screen in image display.

### SUMMARY

One aspect of the present disclosure includes a display module. The display module includes at least one display panel. The display panel includes a substrate, a light-emitting functional layer, a light transmission-covering layer, and an auxiliary structure. The light-emitting functional layer is disposed on one side of the substrate. The light transmission-covering layer is disposed on a side of the light-emitting functional layer away from the substrate. The auxiliary structure is disposed at an edge of the light transmission-covering layer.

Another aspect of the present disclosure includes a display device. The display device includes a display module. The display module includes at least one display panel. The display panel includes a substrate, a light-emitting functional layer, a light transmission-covering layer, and an auxiliary structure. The light-emitting functional layer is disposed on one side of the substrate. The light transmission-covering layer is disposed on a side of the light-emitting functional layer away from the substrate. The auxiliary structure is disposed at an edge of the light transmission-covering layer.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic structural diagram of a display module, in accordance with an embodiment of the present disclosure.

FIG. 2 illustrates a schematic structural diagram of another display module, in accordance with an embodiment of the present disclosure.

FIG. 3 illustrates a schematic structural diagram of another display module, in accordance with an embodiment of the present disclosure.

FIG. 4 illustrates a schematic structural diagram of another display module, in accordance with an embodiment of the present disclosure.

FIG. 5 illustrates a schematic structural diagram of another display module, in accordance with an embodiment of the present disclosure.

FIG. 6 illustrates a schematic structural diagram of another display module, in accordance with an embodiment of the present disclosure.

FIG. 7 illustrates a schematic structural diagram of another display module, in accordance with an embodiment of the present disclosure.

FIG. 8 illustrates a schematic structural diagram of another display module, in accordance with an embodiment of the present disclosure.

FIG. 9 illustrates a schematic structural diagram of another display module, in accordance with an embodiment of the present disclosure.

FIG. 10 illustrates a schematic structural diagram of another display module, in accordance with an embodiment of the present disclosure.

FIG. 11 illustrates a schematic structural diagram of another display module, in accordance with an embodiment of the present disclosure.

FIG. 12 illustrates a schematic structural diagram of another display module, in accordance with an embodiment of the present disclosure.

FIG. 13 illustrates a schematic structural diagram of another display module, in accordance with an embodiment of the present disclosure.

FIG. 14 illustrates a schematic structural diagram of another display module, in accordance with an embodiment of the present disclosure.

FIG. 15 illustrates a schematic structural diagram of another display module, in accordance with an embodiment of the present disclosure.

FIG. 16 illustrates a schematic structural diagram of another display module, in accordance with an embodiment of the present disclosure.

FIG. 17 illustrates a schematic structural diagram of another display module, in accordance with an embodiment of the present disclosure.

FIG. 18 illustrates a schematic structural diagram of another display module, in accordance with an embodiment of the present disclosure.

FIG. 19 illustrates a schematic structural diagram of another display module, in accordance with an embodiment of the present disclosure.

FIG. 20 illustrates a schematic structural diagram of another display module, in accordance with an embodiment of the present disclosure.

FIG. 21 illustrates a schematic structural diagram of another display module, in accordance with an embodiment of the present disclosure.

FIG. 22 illustrates a schematic structural diagram of another display module, in accordance with an embodiment of the present disclosure.

FIG. 23 illustrates a schematic structural diagram of another display module, in accordance with an embodiment of the present disclosure.

FIG. 24 illustrates a schematic structural diagram of another display module, in accordance with an embodiment of the present disclosure.

### DETAILED DESCRIPTION

To make the objectives, technical solutions and advantages of the present disclosure clearer and more explicit, the present disclosure is described in further detail with accompanying drawings and embodiments. It should be understood that the specific exemplary embodiments described herein are only for explaining the present disclosure and are not intended to limit the present disclosure.

Reference will now be made in detail to exemplary embodiments of the present disclosure, which are illustrated in the accompanying drawings. Wherever possible, the same reference numbers will be used throughout the drawings to refer to the same or like parts.

As described in the background section, with the continuous development of display technology, the manufacturing technique of display screens has become increasingly mature, and large-size screens are widely used in various indoor and outdoor occasions. Large-size spliced display screens have replaced traditional large-size display screens and are favored by more and more users due to their portability, low failure rate, long life, and low power consumption, among other benefits and advantages. However, in the existing spliced display screens, there are splicing gaps when adjacent display panels are spliced. When a spliced display screen displays an image, the brightness at the splicing gap is relatively large, which affects the image display performance of the spliced display screen.

Specifically, when preparing a large-size or special-size display screen, multiple display panels are usually spliced together. Considering the processing accuracy of the display panel and avoiding the squeezing between the display panels during splicing, a certain space needs to be reserved between adjacent spliced display panels, and thus there is a splicing gap with a certain width between adjacent display panels. In the existing spliced display screens, light emitted from the side surface of a display panel associated with the splicing gap is usually concentrated and tends to be parallel to its light-emitting direction. Accordingly, when the spliced display screen displays an image, the display brightness at a splicing gap of the spliced display screen tends to be higher than the display brightness of the other remaining areas, resulting in bright lines when the spliced display screen displays the image. This then affects the image display performance of the spliced display screen.

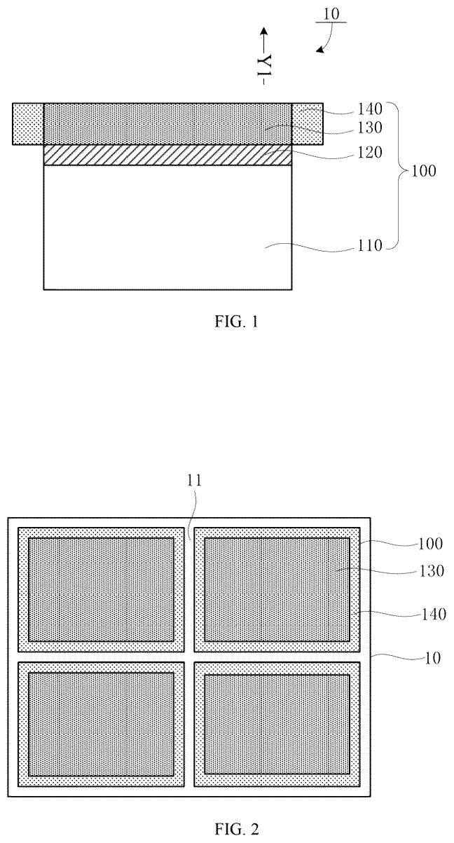

To address the above problems, embodiments of the present disclosure provide a display module and a display device, to improve the display performance of the display device. In order to achieve the above purpose, the technical solution provided by the embodiments of the present disclosure is described in detail hereinafter with reference to FIGS. 1-24.

FIG. 1 illustrates a schematic structural diagram of a display module, in accordance with an embodiment of the present disclosure. The display module 10 disclosed herein includes at least one display panel 100, and the display panel 100 includes a substrate 110. The substrate 110 can be a rigid or flexible substrate, such as a glass substrate. The display module 10 also includes a light-emitting functional layer 120, and the light-emitting functional layer 120 is disposed on one side of substrate 110. The display module 10 further includes a light transmission-covering layer 130, and the light transmission-covering layer 130 is disposed on the side of the light-emitting functional layer 120 away from substrate 110. The display module 10 further includes an auxiliary structure 140, and the auxiliary structure 140 is disposed at an edge of the light transmission-covering layer. In other words, in a light-emitting direction Y1 of display panel 100, the light-emitting functional layer 120 and the light transmission-covering layer 130 are sequentially stacked on the substrate 110. The auxiliary structure 140 is disposed at an edge (or side surface) of light transmission-covering layer 130.

It should be noted that in the display module disclosed herein, the display panel includes an auxiliary structure disposed at an edge of the light transmission-covering layer, and the auxiliary structure is configured to optimize and guide the light emitted from the edge of the light transmission-covering layer, so that the light emitted from the edge of the light transmission-covering layer tends to be transmitted in a direction parallel to a plane where the light transmission-covering layer is disposed. This helps solve the problem in existing spliced display screens where the light emitted from the edge of the light transmission-covering layer is more concentrated in the light-emitting direction of the display panel, thereby helping solve the bright line problem on the edge of a display panel when the display panel displays images. In particular, when a display panel disclosed herein is used in a spliced display module, i.e., when the display module includes a plurality of display panels, where at least some of the display panels are fixedly spliced between adjacent display panels, the bright line problem between the spliced adjacent display panels due to the high brightness at a splicing gap is avoided. Eventually, the display performance of the display device disclosed herein is improved. In addition, in the embodiments of the present disclosure, the auxiliary structure is disposed at the edge of the light transmission-covering layer, so the auxiliary structure can also play a certain buffering role. This helps solve the problem that the edge of the light transmission-covering layer may be easily damaged when the display panel is impacted by force. This further improves the reliability of the display panel.

As shown in FIG. 1, the display module 10 disclosed herein may include a single display panel 100. Alternatively, in some embodiments of the present disclosure, the display module may also include a plurality of display panels, where at least some of the display panels are fixedly spliced. Specifically, FIG. 2 illustrates a schematic structural diagram of another display module disclosed herein, where the display module 10 includes a plurality of display panels 100. FIG. 2 is illustrated by taking 4 display panels 100 as an example, but the number of display panels 100 is not limited thereto. In FIG. 2, two adjacent display panels 100 are fixedly spliced, and a splicing gap 11 is formed between the light transmission-covering layers 130 of the two fixedly spliced display panels 100.

It should be noted that, for ease of understanding, the size of the splicing gap 11 is exaggerated in the illustrated embodiments. In some embodiments, the splicing gap 11 may be a gap that is not perceptible to a naked eye. In some embodiments, the splicing gap 11 may be an interface through which two adjacent display panels 100 contact.

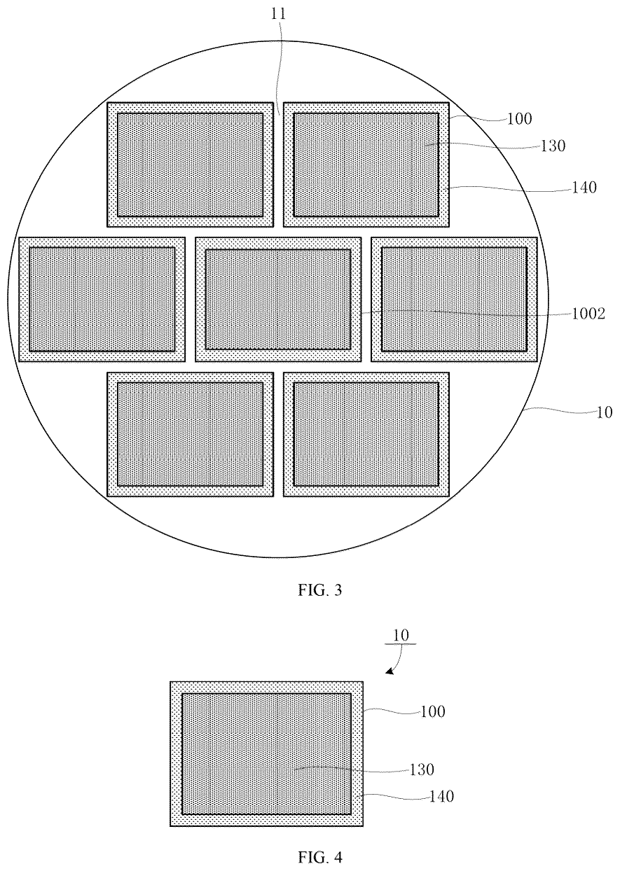

In some embodiments, when two adjacent display panels 100 are spliced, the two display panels can be fixed in the designated area by certain fixing means such as a fixing bracket or fixing glue, which is not limited in the present disclosure. Referring continuously to FIG. 2, when the display module 10 disclosed herein includes multiple display panels 100, the multiple display panels 100 can be fixedly spliced to make the display module 10 rectangular. Alternatively, referring to FIG. 3, which is a schematic structural diagram of another display module disclosed herein, the display module 10 also includes multiple display panels 100. FIG. 3 is illustrated by including 7 display panels 100 as an example, but the number of display panels 100 is not limited thereto. In FIG. 3, the adjacent two display panels 100 are fixedly spliced, and there is a splicing gap 11 between the light transmission-covering layers 130 of the two fixedly spliced display panels 100. When two adjacent display panels 100 are spliced, the display panels can be fixed in a designated area by certain fixing means such as a fixing bracket or fixing glue, which is not limited in the present disclosure. Referring continuously to FIG. 3, when the display module 10 disclosed herein includes a plurality of display panels 100, the display module 10 may be circular in shape after the plurality of display panels 100 are fixedly spliced.

It should be noted that the present disclosure only uses the rectangular display module 10 shown in FIG. 2 and the circular display module 10 shown in FIG. 3 as examples for schematic illustration. In some embodiments, the display module can also be a display module of other regular polygonal shapes or elliptical shapes, or can also be a display module of irregular shapes. To obtain these different shapes, it may be necessary to specifically develop a splicing and arrangement order of display panels according to the actual shape of the display module and the number of display panels to be included therein, which is not limited in the present disclosure. Similarly, the present disclosure also does not impose specific restrictions on the shape of a display panel, which can be a regular polygon, circle, or ellipse, etc., or an irregular shape, which can be specifically designed according to actual needs.

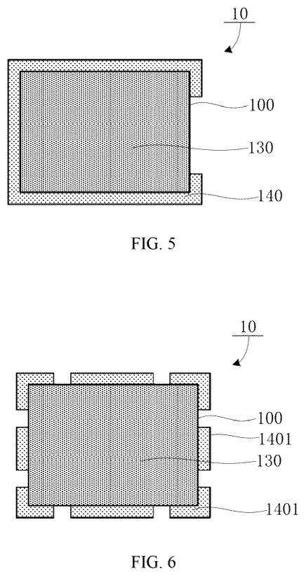

In some embodiments, the auxiliary structure is disposed at the edge of the light transmission-covering layer. Specifically, the auxiliary structure can be disposed at a side surface of the light transmission-covering layer, where the light transmission-covering layer includes a top surface facing away from the substrate and a bottom surface facing the substrate, and a side surface between the top surface and bottom surface. The side surface of the light transmission-covering layer is connected with the top surface and the bottom surface. Referring to FIGS. 1 and 4, in a schematic structural diagram of another display module disclosed herein, the auxiliary structure 140 can be a continuous structure arranged along the edge surrounding the light transmission-covering layer 130. In one embodiment, the auxiliary structure 140 can be a continuous closed-loop structure arranged along the edge surrounding the light transmission-covering layer 130. Alternatively, referring to FIG. 5, another form of the auxiliary structure 140 disclosed herein can be a continuous non-closed loop structure arranged along the edge surrounding the light transmission-covering layer 130. The size of the opened gap in the non-closed loop (i.e., the size of the gap between the two ends of the auxiliary structure 140 along the edge surrounding the light transmission-covering layer 130) is not specifically limited in the present disclosure, and can be specifically designed according to actual needs. In some embodiments, the auxiliary structure disclosed herein can also be a discontinuous structure arranged along the edge surrounding the light transmission-covering layer. Referring specifically to FIG. 6, in a schematic structural diagram of another display module disclosed herein, the auxiliary structure 140 is a discontinuous structure arranged along the edge surrounding the light transmission-covering layer 130. In the illustrated embodiment, the auxiliary structure 140 is divided into a plurality of sub-auxiliary structures 1401 arranged along the edge surrounding the light transmission-covering layer 130. There is a gap between two adjacent sub-auxiliary structures 1401, where the size of a gap between two adjacent sub-auxiliary structures 1401 is not specifically limited in the present disclosure.

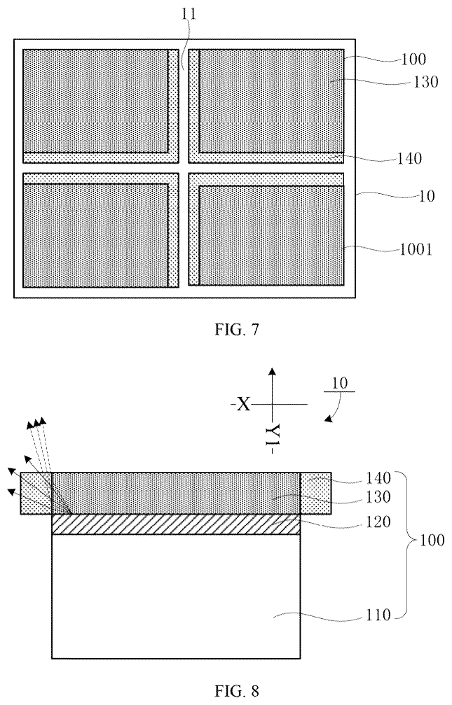

In some embodiments, for a display panel included in the display module disclosed herein, its auxiliary structure can be a continuous structure or a discontinuous structure, which is not limited in the disclosure. For example, referring to FIG. 7, in a schematic structural diagram of another display module disclosed herein, the edge area of the display module 10 can be wrapped and covered by a frame structure. Accordingly, for a display panel 100 disposed along the edge of the display module 10, the side adjacent to the edge of the display module 10 can not be configured with an auxiliary structure 140. Accordingly, for a display panel 100 disposed along the edge of the display module 10, specifically, for a display panel 1001 in FIG. 7, an area associated with an adjacent display panel 100 can be provided with an auxiliary structure 140, while an area of the display panel 1001 adjacent to the edge of the display module 10 can no longer be configured with an auxiliary structure 140. The display panel 1001 can be designated as a panel including a continuous non-closed loop auxiliary structure 140. Alternatively, refer to FIG. 3, which shows a display panel 1002 in the central area. The display panel 1002 is surrounded by other display panels 100. Accordingly, in order to improve the display performance of the display module 10, the display panel 1002 can be configured as a display panel including a continuous closed-loop auxiliary structure 140. Accordingly, when optimizing the design of a display module disclosed herein, a display panel with an auxiliary structure having a continuous structure or a discontinuous structure can be selected according to factors such as the position of the display panel in the display module, which is not limited in the present disclosure.

FIG. 8 illustrates a schematic structural diagram of another display module, in accordance with an embodiment of the present disclosure. In a direction X parallel to the plane where the light transmission-covering layer 130 is disposed, the auxiliary structure 140 extends over the edge of the substrate 110. The auxiliary structure 140 is configured to optimize and guide the light emitted from the edge of the light transmission-covering layer 130, specifically, the side surface of the light transmission-covering layer 130. Compared to the problem occurring in existing spliced display screens where light emitted from the edge of the light transmission-covering layer 130 is more concentrated toward the light-emitting direction Y1 of a display panel 100, the auxiliary structure 140 disclosed herein can guide the light emitted from the edge of the light transmission-covering layer 130 to be more tuned toward the direction X parallel to the plane where the light transmission-covering layer 130 is disposed, thereby helping solve the bright line problem at the edge of the display panel 100 in image display. As shown in FIG. 8, the dotted arrow indicates that light is more concentrated toward the light-emitting direction Y1 of the display panel 100, and the solid arrow indicates that light is tuned toward the direction X parallel to the plane where the light transmission-covering layer 130 is disposed. In some embodiments, compared with the internal area of a display panel, in a lateral direction (e.g., the X direction), the display panel is directly cut off or exposed at the side surface, and thus the direction of the light emitted there can be relatively complicated. By configuring an auxiliary structure 140 to extend beyond the edge of the substrate 100, some light emitted from areas outside the coverage of the display panel can be corrected. The light emitted from the edge of the light transmission-covering layer 130 can be then better optimized and guided, further facilitating solving the bright line problem along the edge of a display panel 100, weakening the light emission difference between the internal display area and the edge display area, thereby improving the display performance of the display panel 100. At the same time, when the display panel 100 disclosed herein is applied to the spliced display module 10, the bright line problem between adjacent display panels 100 due to the high brightness at the splicing gap can be prevented, thereby eventually improving the display performance of the display device.

It should be noted that the light-emitting direction of the display panel disclosed herein is directional, so the light-emitting direction Y1 of the display panel 100 shown in FIG. 8 is marked with an arrow. The light-emitting direction parallel to the surface where the light transmission-covering layer is disposed is not directional, so the direction X shown in FIGS. 1 and 8 is not marked with an arrow.

Continuing to refer to FIGS. 2 and 3, the display module 10 disclosed herein includes at least two display panels 100, where the display panels 100 are fixedly spliced, and there is a splicing gap 11 between the light transmission-covering layers 130 of two adjacent display panels 100. At least part of the auxiliary structure 140 is disposed at the splicing gap 11. Accordingly, when at least part of the auxiliary structure 140 is disposed at the splicing gap 11, it is possible to optimize and guide the light emitted from the edge of the light transmission-covering layer 130, thereby helping solve the bright line problem between adjacent display panels 100 caused by the high brightness at the splicing gap 11. This eventually improves the display performance of the display module 10. At the same time, when at least part of the auxiliary structure 140 is disposed at the splicing gap 11, the splicing gap 11 can be covered to a certain extent by the auxiliary structure 140. This helps solve the visual discontinuity problem of the display module 10 caused by the presence of the splicing gap 11, besides the improved display performance of the display module 10 described above.

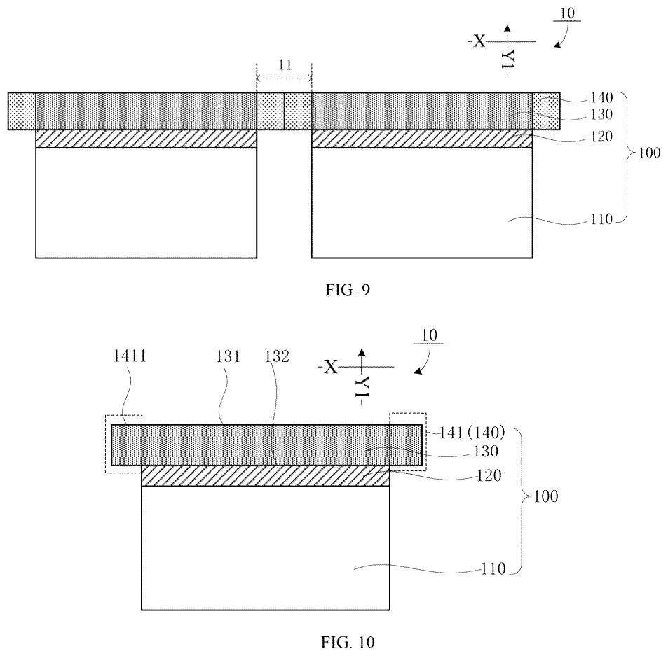

Furthermore, the auxiliary structures between adjacent displays can be in direct contact with each other, thereby achieving the purpose of covering a splicing gap. Referring to FIG. 9, in a schematic structural diagram of another display module, the auxiliary structures 140 of two adjacent display panels 100 are in direct contact with each other. On a reference plane parallel to the plane where the light transmission-covering layer 130 is disposed, the orthographic projections of the auxiliary structures 140 of the two adjacent display panels 100 cover the orthographic projection of the splicing gap 11. The splicing gap 11 is thus completely covered by the auxiliary structures 140, which not only further improves the display performance of the display module 10, but also further improves the visual continuity of the display module 10. The auxiliary structure disclosed herein can optimize and guide the light emitted from the edge of the light transmission-covering layer, so that the light emitted from the edge of the light transmission-covering layer tends to be transmitted in a direction parallel to the plane where the light transmission-covering layer is disposed. This helps solve the problem in existing spliced display screens where light emitted from the edge of the light transmission-covering layer is more concentrated in the light-emitting direction of the display panel, thereby helping solve the bright line problem when the display module displays images. In some embodiments, the auxiliary structure can guide the light emitted from the edge of the light transmission-covering layer to propagate along its original optical path. After the light emitted from the edge of the light transmission-covering layer propagates along its original optical path for a period of time, the auxiliary structure then guides the optical path to change to be transmitted in a direction parallel to the plane where the light transmission-covering layer is disposed. In some embodiments, the auxiliary structure can also directly guide the optical path of the light emitted from the edge of the light transmission-covering layer to be transmitted in a direction parallel to the plane where the light transmission-covering layer is disposed. The present disclosure does not limit the specific ways of optical path guidance, and the exact way of light guiding and transmission is determined based on the specific type of auxiliary structure included in a display panel. The auxiliary structure disclosed herein is described in more detail hereinafter in conjunction with the accompanying drawings.

FIG. 10 illustrates a schematic structural diagram of another display module, in accordance with an embodiment of the present disclosure. In the illustrated embodiment, the auxiliary structure 140 includes a light-transmitting portion 141 connected to the side surface of the light transmission-covering layer 130. The side surface of the light transmission-covering layer 130 is the side wall of the light transmission-covering layer 130. In other words, the light transmission-covering layer 130 includes a top face 131 facing away from the substrate 110 and a bottom face 132 facing the substrate 110. The side surface of the light transmission-covering layer 130 is located between the top face 131 and the bottom face 132, and is connected to the top face 131 and the bottom face 132. After light emitted from the side surface of the light transmission-covering layer 130 enters the light-transmitting portion 141, the light-transmitting portion 141 can guide the light to be transmitted in the direction X parallel to the plane where the light transmission-covering layer 130 is disposed, thereby helping solve the bright line problem when the display module 10 displays an image.

The continuous form of the light-transmitting portion disclosed herein can be the same as the continuous form of the auxiliary structure described above. Specifically, in combination with the display module 10 shown in FIGS. 4-6, the light-transmitting portion 141 disclosed herein can be in the continuous form of the auxiliary structure 140 as shown in FIG. 4. In other words, the light-transmitting portion 141 can be a continuous closed-loop structure arranged along the edge surrounding the light transmission-covering layer 130. Alternatively, the light-transmitting portion 141 can be in the continuous form of the auxiliary structure 140 as shown in FIG. 5. In other words, the light-transmitting portion 141 can be a continuous non-closed-loop structure arranged along the edge surrounding the light transmission-covering layer 130. Alternatively, the light-transmitting portion 141 can be in the discontinuous form of the auxiliary structure 140 as shown in FIG. 6. In other words, the light-transmitting portion 141 can be a discontinuous structure arranged along the edge surrounding the light transmission-covering layer 130. The continuous form of the light-transmitting portion is not limited in the present disclosure. In addition, the light-transmitting portions of two adjacent display panels disclosed herein are in direct contact with each other. On a reference plane parallel to the plane where the light transmission-covering layer is disposed, the orthographic projections of the light-transmitting portions of the two adjacent display panels cover the orthographic projection of the splicing gap. The splicing gap is thus completely covered by the light-transmitting portions, which not only further improves the display performance of the display module, but also further improves the visual continuity of the display module.

In some embodiments, the light-transmitting portion and the light transmission-covering layer disclosed herein may both be composed of light-transmitting adhesive materials. For example, the material of at least one of the light-transmitting portion and the light transmission-covering layer may be polyethylene terephthalate (PET), triacetyl cellulose (TAC), or polyimide (PI), etc. In some embodiments, the light-transmitting portion may be a light-transmitting structure independent of the light transmission-covering layer. The material of the light-transmitting portion may be the same as or different from the material of the light transmission-covering layer, each of which can be specifically selected according to actual needs. Alternatively, the light-transmitting portion and the light transmission-covering layer disclosed herein may be an integral continuous structure, and thus the integral molding of the light-transmitting portion and the light transmission-covering layer can not only simplify the preparation process, but also simplify the components of a display panel, which thus improves the assembly compactness of the display panel. Continuing to refer to FIG. 10, the light-transmitting portion 141 disclosed herein includes a top surface 1411 on the light-emitting side Y1 of the display panel 100. The light transmission-covering layer 130 includes a top surface 131 on the side away from the substrate 110. The top surface 1411 of the light-transmitting portion 141 is flush with the top surface 131 of the light transmission-covering layer 130. In other words, the top surface 1411 of the light-transmitting portion 141 and the top surface 131 of the light transmission-covering layer 130 are positioned in a same plane. This ensures the consistency of light emission between the top surface 1411 of the light-transmitting portion 141 and the top surface 131 of the light transmission-covering layer 130, thereby improving the display performance of the display module 10. In some embodiments, the light-transmitting portion 141 and the light transmission-covering layer 130 disclosed herein can be an integrated continuous structure, which can simplify the manufacturing process of the display panel 100 and improve the assembly compactness of the display panel 100. In some embodiments, the top surfaces of the light-transmitting portion 141 and the light transmission-covering layer 130 disclosed herein may have a matte effect, which can not only protect the light-emitting functional layer 120 but also provide anti-scratch and anti-fingerprint functions.

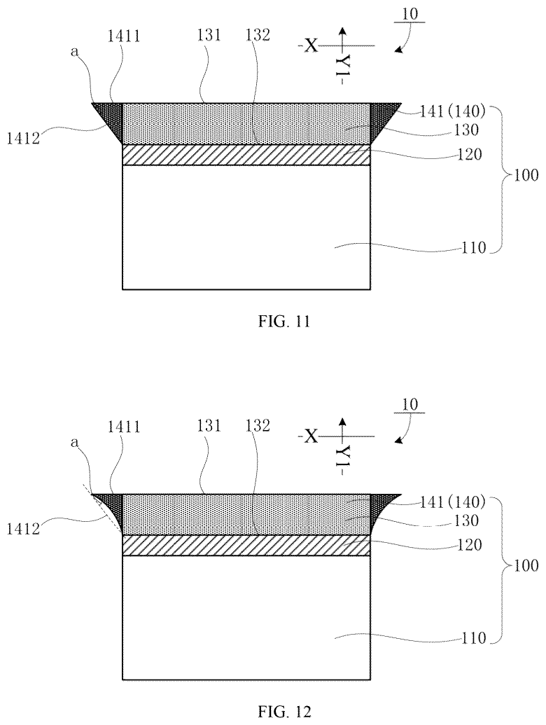

FIG. 11 illustrates a schematic structural diagram of another display module, in accordance with an embodiment of the present disclosure. In the illustrated embodiment, the light-transmitting portion 141 disclosed herein includes a side surface facing away from the light transmission-covering layer 130. The side surface of the light-transmitting portion 141 includes a first side surface 1412. Along the light-emitting direction Y1 of the display panel 100, the first side surface 1412 is inclined toward the side facing away from the light transmission-covering layer 130. In other words, in the portion of the light-transmitting portion 141 corresponding to the first side surface 1412, the width of the light-transmitting portion 141 in the direction X parallel to the plane where the light transmission-covering layer 130 is disposed tends to increase along the light-emitting direction Y1 of the display panel 100. In other words, the light-transmitting portion 141 disclosed herein has its first side surface 1412 configured as an inclined surface. When light is emitted from the side surface of the light transmission-covering layer 130 to the light-transmitting portion 141 connected thereto, the light-transmitting portion 141 can guide the light to be transmitted inside the light-transmitting portion 141 along its original propagation path. When the light is transmitted to the first side surface 1412 for emission, since the first side surface 1412 is an inclined surface inclined toward the side away from the light transmission-covering layer 130, the light is refracted after being emitted from the first side surface 1412, where the refracted light tends to be parallel to the direction X of the plane where the light transmission-covering layer 130 is disposed. Accordingly, the light emitted from the side surface of the light transmission-covering layer 130 is guided by the light-transmitting portion 141 along two transmission paths, thereby achieving the purpose of solving the bright line problem when the display module 10 displays an image. This improves the display performance of the display module 10.

In some embodiments, the present disclosure does not impose any specific restrictions on the degree of inclination of the first side surface 1412. Continuing to refer to FIG. 11, in a cross-section parallel to the light-emitting direction Y1 of the display panel 100 and perpendicular to the edge of the light transmission-covering layer 130 adjacent to the light-transmitting portion 141, the inclination angle a between the endpoint line between the two end points of the first side surface 1412 and the plane where the top surface 131 of the light transmission-covering layer 130 is disposed is between 60-85 degrees. By optimizing the specific value of the inclination angle a, the mechanical strength and optical effect of the light-transmitting portion 141 are ensured to be optimal. The inclination angle a is the angle between the endpoint line toward the light transmission-covering layer 130 and the substrate 110 and the plane where the top surface 131 of the light transmission-covering layer 130 is disposed. The degree of inclination of the first side surface 1412 disclosed herein can be indicated by the inclination angle a. The greater the degree of inclination of the first side surface 1412, the smaller the inclination angle a. The smaller the degree of inclination of the first side surface 1412, the larger the inclination angle a. It should be noted that whenever the inclination angle is discussed in the following description of the embodiments of the present disclosure, the inclination angle is the angle, between the endpoint line between the two end points of the side surface and the plane where the top surface of the light transmission-covering layer is disposed, in a cross-section parallel to the light-emitting direction of the display panel and perpendicular to the edge of the light transmission-covering layer adjacent to the light-transmitting portion.

FIG. 11 shows a schematic diagram of the inclination angle a when the first side surface 1412 is an inclined plane. In some embodiments, the first side surface disclosed herein can also be an inner concave surface that is recessed toward the side of the light transmission-covering layer. FIG. 12 illustrates a schematic structural diagram of another display module, in accordance with an embodiment of the present disclosure. In the illustrated embodiment, the first side surface 1412 can be an inner concave surface recessed toward the side of the light transmission-covering layer 130. In a cross-section parallel to the light-emitting direction Y1 of the display panel 100 and perpendicular to the edge of the light transmission-covering layer 130 adjacent to the light-transmitting portion 141, an inclination angle a between an endpoint line between two endpoints of the first side surface 1412 and a plane where the top surface 131 of the light transmission-covering layer 130 is disposed is between 60-85 degrees. By optimizing the specific value of the inclination angle a, the mechanical strength and optical effect of the light-transmitting portion 141 are ensured to be optimal. The inclination angle a is an angle between the endpoint line toward the side of the light transmission-covering layer 130 and the side of the substrate 110 and the plane where the top surface 131 of the light transmission-covering layer 130 is disposed.

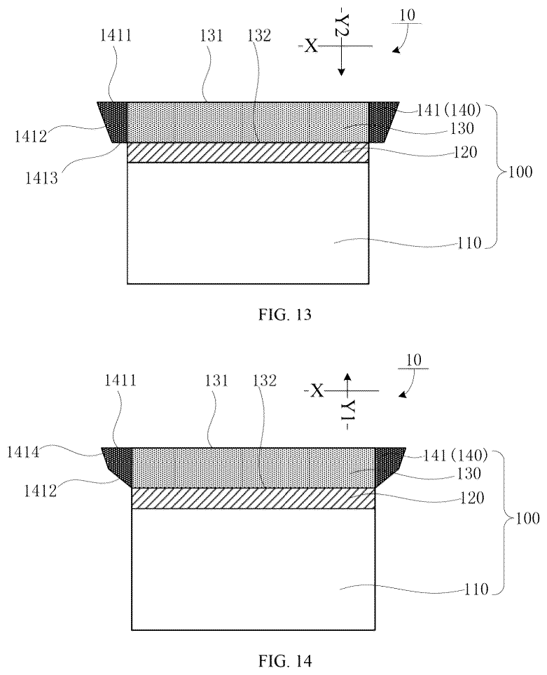

The shape of the light-transmitting portion disclosed herein can be any shape, so that the display panel can adapt to the splicing structure of different display modules. The several specific shapes of light-transmitting portions are described hereinafter with reference to the accompanying drawings. Continuing to refer to FIG. 11, the bottom edge of the first side surface 1412 disclosed herein facing the substrate 110 is positioned at the connecting part between the light-transmitting portion 141 and the light transmission-covering layer 130. Further, the bottom edge of the first side surface 1412 facing the substrate 110 is connected to the edge of the bottom surface 132 of the light transmission-covering layer 130. That is, on a reference plane parallel to the plane where the light transmission-covering layer 130 is disposed, the orthographic projection of the bottom edge of the first side surface 1412 facing the substrate 110 overlaps with the orthographic projection of the connecting part of the side surface of the light-transmitting portion 141 and the light transmission-covering layer 130. Further, the bottom edge of the first side surface 1412 facing the substrate 110 is connected to the edge of the bottom surface 132 of the light transmission-covering layer 130. Alternatively, FIG. 13 illustrates a schematic structural diagram of another display module, in accordance with an embodiment of the present disclosure. In the illustrated embodiment, the light-transmitting portion 141 disclosed herein includes a bottom surface 1413 on the side of the opposite direction Y2 of the light-emitting direction of the display panel 100. The bottom surface 1413 of the light-transmitting portion 141 is connected with the first side surface 1412. In addition, the bottom surface 1413 of the light-transmitting portion 141 disclosed herein abuts the edge line of the light transmission-covering layer 130, and is connected with the edge line of the bottom surface 132 of the light transmission-covering layer 130. In some embodiments, by designing the light-transmitting portion 141 into different shapes, the application range of the display panel 100 is enlarged, so that the display panel 100 is applicable to the splicing structure of different display modules 10.

In some embodiments, on a reference plane parallel to the plane where the light transmission-covering layer is disposed, the orthographic projection of the bottom edge of the first side surface toward the side of the substrate overlaps with the orthographic projection of the substrate. On the basis of ensuring that the bright line problem of the display screen of the display module can be solved by the light-transmitting portion, since the first side surface of the light-transmitting portion is an inclined surface inclined toward the side away from the light transmission-covering layer in the light-emitting direction of the display panel, the light-transmitting portion will exceed the edge of the substrate in the direction parallel to the plane where the light transmission-covering layer is disposed. This further improves the light-transmitting portion's optimized guiding effect on the light emitted from the side surface of the light transmission-covering layer, and thus further improves the display performance of the display module. Specifically, as shown in FIG. 11, the bottom edge of the first side surface 1412 toward the side of the substrate 110 corresponds to the edge line of the substrate 110, so that on a reference plane parallel to the plane where the light transmission-covering layer 130 is disposed, the orthographic projection of the bottom edge of the first side surface 1412 toward the side of the substrate 110 overlaps with the edge line of the orthographic projection of the substrate 110. In some embodiments, in the light-emitting direction Y1 of the display panel 100, the extension of the side surface of the substrate 110 and the extension of the side surface of the light transmission-covering layer 130 are both on the same plane. In other words, on a reference plane parallel to the plane where the light transmission-covering layer 130 is disposed, the edge line of the orthographic projection of the substrate 110 on the reference plane and the edge line of the orthographic projection of the light transmission-covering layer 130 on the reference plane can overlap, which is not limited in the present disclosure.

The first side surface disclosed herein may be the entire side surface of the light-transmitting portion. Alternatively, the first side surface may also be a portion of the entire side surface of the light-transmitting portion, and the side surface of the light-transmitting portion may also include other shapes of side surfaces. Specifically, FIG. 14 illustrates a schematic structural diagram of another display module, where the side surface of the light-transmitting portion 141 disclosed herein also includes a second side surface 1414. In the light-emitting direction Y1 of the display panel 100, the second side surface 1414 is disposed on the side of the first side surface 1412 away from the substrate 110. Along the light-emitting direction Y1 of the display panel 100, the second side surface 1414 is inclined toward the side away from the light transmission-covering layer 130. The first side surface 1412 and the second side surface 1414 are both inclined surfaces, and the first side surface 1412 and the second side surface 1414 are inclined in the same direction. When light is emitted from the side surface of the light transmission-covering layer 130 to the light-transmitting portion 141 connected thereto, the light-transmitting portion 141 can guide the light to be transmitted inside the light-transmitting portion 141 along its original propagation path. When the light is transmitted to the first side surface 1412 and the second side surface 1414 for emission, since the first side surface 1412 and the second side surface 1414 are both inclined surfaces inclined toward the side away from the light transmission-covering layer 130, the light is refracted when being emitted from the first side surface 1412 and the second side surface 1414. The refracted light tends to be parallel to the direction X of the plane where the light transmission-covering layer 130 is disposed, thereby helping solve the problem of high brightness along the edge of a display panel 100. This allows to achieve the objective of solving the bright line problem when the display module 10 displays an image, thereby improving the display performance of the display module 10. It should be noted that the embodiments of the present disclosure do not impose any specific restrictions on the degree of inclination of the first side surface 1412 and the second side surface 1414, which can be specifically designed according to actual needs. For example, the degree of inclination of the first side surface 1412 may be greater than the degree of inclination of the second side surface 1414.

Similarly, the degree of inclination of the second side surface 1414 can also be indicated by an inclination angle. The inclination angle corresponding to the second side surface 1414 is defined as, in a cross-section parallel to the light-emitting direction Y1 of the display panel 100 and perpendicular to the edge of the light transmission-covering layer 130 adjacent to the light-transmitting portion 141, an inclination angle between the end line between the two end points of the second side surface 1414 and the plane where the top surface 131 of the light transmission-covering layer 130 is disposed. The inclination angle corresponding to the second side surface 1414 can also be between 60-85 degrees. In some embodiments, when the degree of inclination of the first side surface 1412 is greater than the degree of inclination of the second side surface 1414, the inclination angle corresponding to the first side surface 1412 is smaller than the inclination angle corresponding to the second side surface 1414. Conversely, when the degree of inclination of the first side surface 1412 is smaller than the degree of inclination of the second side surface 1414, the inclination angle corresponding to the first side surface 1412 is larger than the inclination angle corresponding to the second side surface 1414.

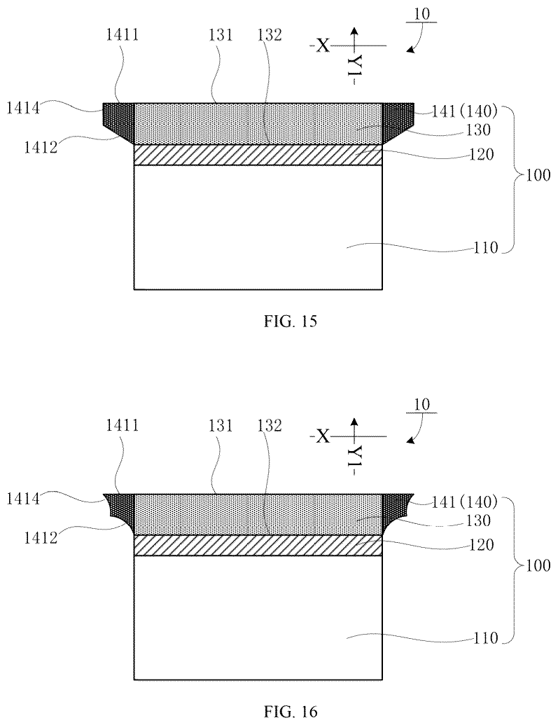

The second side surface disclosed herein may be an inclined surface relative to the light-emitting direction of the display panel. Alternatively, the second side surface disclosed herein may also be a surface parallel to the light-emitting direction of the display panel. Specifically, referring to FIG. 15, in a schematic structural diagram of another display module disclosed herein, the side surface of the light-transmitting portion 141 also includes a second side surface 1414. In the light-emitting direction Y1 of the display panel 100, the second side surface 1414 is disposed on the side of the first side surface 1412 away from the substrate 110. The second side surface 1414 is parallel to the light-emitting direction Y1 of the display panel 100. It can be seen that when light is emitted from the side surface of the light transmission-covering layer 130 towards the light-transmitting portion 141 connected thereto, the light-transmitting portion 141 can guide the light to be transmitted inside the light-transmitting portion 141 along its original propagation path. When the light is transmitted to the first side surface 1412 and the second side surface 1414 for emission, since the first side surface 1412 is an inclined surface inclined toward the side away from the light transmission-covering layer 130, the light is refracted after being emitted from the first side surface 1412. The refracted light tends to be parallel to the direction X parallel to the plane where the light transmission-covering layer 130 is disposed, thereby helping solve the problem of high brightness along the edge of the display panel 100. This allows to achieve the objective of solving the bright line problem when the display module 10 displays an image, thereby improving the display performance of the display module 10.

Referring continuously to FIGS. 11, 13, and 14, the first side surface 1412 disclosed herein can be an inclined plane. In other words, the first side surface 1412 is an inclined plane, and the first side surface 1412 is a flat surface. Alternatively, referring to FIG. 16, in a schematic structural diagram of another display module disclosed herein, the first side surface 1412 is an inner concave surface that is recessed toward the side of the light transmission-covering layer 130. Through the first side surface 1412, not only can the light emitted therefrom be refracted to propagate in the direction X parallel to the plane where the light transmission-covering layer 130 is disposed, but the light can also be scattered when emitted through the inner concave surface. This prevents the light from being concentrated at the edge of the display panel 100, thereby further helping solve the bright line problem that occurs when the display module 10 displays an image. Referring continuously to FIG. 16, the light-transmitting portion 141 disclosed herein includes a second side surface 1414. When the second side surface 1414 has the same inclination direction as the first side surface 1412, at least one of the second side surface 1414 and the first side surface 1412 can be an inner concave surface that is recessed toward the side of the light transmission-covering layer 130, which is not limited in the present disclosure. The inner concave surface is configured to further improve the bright line problem that occurs when the display module 10 displays an image.

On the basis of solving the bright line problem of the display module, in order to ensure the dimensional consistency of the display panel, the degree of inclination of the first side surface corresponding to light-transmitting portions of different thicknesses in the light-emitting direction of the display panel can be set to be different. Specifically, the thickness of at least part of the light-transmitting portion in the light-emitting direction of the display panel is inversely proportional to the degree of inclination of the first side surface corresponding to the light-transmitting portion. In other words, the thickness of at least part of the light-transmitting portions in the light-emitting direction of the display panel is proportional to the corresponding inclination angle of the first side surface corresponding to the light-transmitting portion. The light-transmitting portion of different thicknesses can be understood as different thicknesses of different areas of the light-transmitting portion on a same display panel. Alternatively, the light-transmitting portion of different thicknesses can also be understood as different thicknesses of different light-transmitting portions on different display panels. It should be noted that the different thicknesses of the same light-transmitting portion refer to a situation where the light-transmitting portion is divided into multiple sections along its extension direction, and the thickness of at least one section in the light-emitting direction of the display panel is different from the thicknesses of the other sections. In other words, the different thicknesses of the same light-transmitting portion refer to a situation where the light-transmitting portion is divided into multiple sub-light-transmitting portions along the edge surrounding the light transmission-covering layer. The thickness of at least one sub-light-transmitting portion in the light-emitting direction of the display panel is different from the thicknesses of the other sub-light-transmitting portions. The different thicknesses of the light-transmitting portion of different display panels can refer to a situation that the thickness of at least part of the light-transmitting portion in at least one display panel in the same display module in the light-emitting direction of the display panel is different from the thickness of at least part of the light-transmitting portions of other display panels. No matter what the situations of the light-transmitting portion of different thicknesses are, the rule that the thickness of the light-transmitting portion is inversely proportional to the degree of inclination of the first side surface corresponding to the light-transmitting portion is to be satisfied.

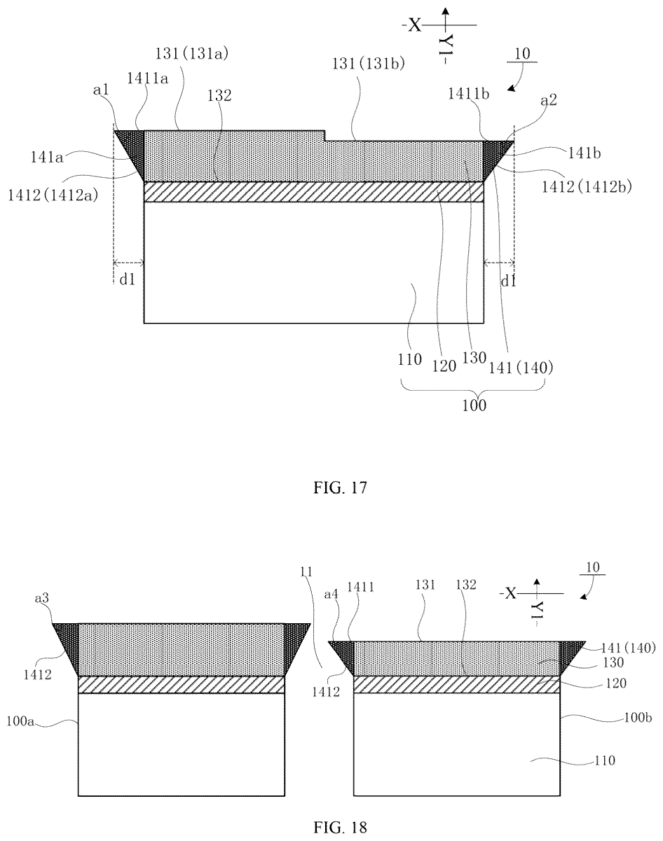

FIG. 17 illustrates a schematic structural diagram of another display module, in accordance with an embodiment of the present disclosure. In the illustrated embodiment, in the same light-transmitting portion 141 of the same display panel 100, the light-transmitting portion 141 includes a first sub-light-transmitting portion 141a and a second sub-light-transmitting portion 141b. The thickness of the first sub-light-transmitting portion 141a in the light-emitting direction Y1 of the display panel 100 is greater than the thickness of the second sub-light-transmitting portion 141b in the light-emitting direction Y1 of the display panel 100. The degree of inclination of the first side surface 1412 corresponding to the first sub-light-transmitting portion 141a is less than the degree of inclination of the first side surface 1412 corresponding to the second sub-light-transmitting portion 141b. In other words, the inclination angle a1 of the first side surface 1412 corresponding to the first sub-light-transmitting portion 141a is greater than the inclination angle a2 of the first side surface 1412 corresponding to the second sub-light-transmitting portion 141b. Thus, the light emitted from the side surface of the light transmission-covering layer 130 is guided by the light-transmitting portion 141 so as to be in the direction X parallel to the plane where the light transmission-covering layer 130 is disposed. This allows to achieve the objective of solving the bright line problem when the display module 10 displays an image. Furthermore, the thickness of the first sub-light-transmitting portion 141a disclosed herein is greater than the thickness of the second sub-light-transmitting portion 141b. By designing the degree of inclination of the first side surface 1412 corresponding to the first sub-light-transmitting portion 141a to be less than the degree of inclination of the first side surface 1412 corresponding to the second sub-light-transmitting portion 141b, it can be ensured that the dimension of each region of the light-transmitting portion 141, in the direction X parallel to the plane where the light transmission-covering layer 130 is disposed, is consistent despite different thicknesses of different regions of the light-transmitting portion 141. For example, as shown in FIG. 17, in the direction X parallel to the plane where the light transmission-covering layer 130 is disposed, the dimension dl of the first sub-light-transmitting portion 141a is the same as the dimension dl of the second sub-light-transmitting portion 141b. The dimensional consistency of the display panel 100 is thus improved.

It should be noted that, under situations where different regions of the same light-transmitting portion 141 have different thicknesses in the light-emitting direction Y1 of the display panel 100, when the top surface 1411 of the light-transmitting portion 141 is flush with the top surface 131 of a light transmission-covering layer 130, the top surface 1411 of the light-transmitting portion 141 can be flush with the top surface 131 of an adjacent portion of the light transmission-covering layer 130. The top surface 131 of the light transmission-covering layer 130 shown in FIG. 17 includes a first top surface 131a and a second top surface 131b. In the light-emitting direction Y1 of the display panel 100, the first top surface 131a is higher than the second top surface 131b. The first top surface 131a is flush with the top surface 1411a of the first sub-light-transmitting portion 141a, and the second top surface 131b is flush with the top surface 1411b of the second sub-light-transmitting portion 141b. In some embodiments, the first top surface 131a and the second top surface 131b disclosed herein can be connected by a cliff surface parallel to the light-emitting direction Y1 of the display panel 100, or can be connected through a sloped inclined surface to achieve a buffer connection, which is not limited in the present disclosure and the specific design may be determined according to actual needs. The inclination angle a1 corresponding to the first side surface 1412a of the first sub-light-transmitting portion 141a is defined as, in a cross-section parallel to the light-emitting direction Y1 of the display panel 100 and perpendicular to the edge of the light transmission-covering layer 130 adjacent to the first sub-light-transmitting portion 141a, an angle between the endpoint line between the two end points of the first side surface 1412a and the plane where the top surface 131a of the corresponding portion of the light transmission-covering layer 130 adjacent to the first sub-light-transmitting portion 141a is disposed. The inclination angle a2 corresponding to the first side surface 1412b of the second sub-light-transmitting portion 141b is defined as, in a cross-section parallel to the light-emitting direction Y1 of the display panel 100 and perpendicular to the edge of the light transmission-covering layer 130 adjacent to the second sub-light-transmitting portion 141b, an angle between the endpoint line between the two end points of the first side surface 1412b and the plane where the top surface 131b of the corresponding portion of the light transmission-covering layer 130 adjacent to the second sub-light-transmitting portion 141b is disposed.

FIG. 18 illustrates a schematic structural diagram of another display panel, in accordance with an embodiment of the present disclosure. In the illustrated embodiment, the display module 10 includes at least two display panels. The at least two display panels include a first display panel 100a and a second display panel 100b. The thickness of at least a portion of the light-transmitting portion 141 of the first display panel 100a in the light-emitting direction Y1 of the display panel is greater than the thickness of at least a portion of the light-transmitting portion 141 of the second display panel 100b in the light-emitting direction Y1 of the display panel. The degree of inclination of the first side surface 1412 of the at least portion of the light-transmitting portion 141 of the first display panel 100a is less than the degree of inclination of the first side surface 1412 of the at least portion of the light-transmitting portion 141 of the second display panel 100b. In other words, the inclination angle a3 corresponding to the first side surface 1412 of the at least portion of the light-transmitting portion 141 of the first display panel 100a is greater than the inclination angle a4 corresponding to the first side surface 1412 of the at least portion of the light-transmitting portion 141 of the second display panel 100b. Accordingly, on the basis of improving the display performance of the display module 10 by setting the light-transmitting portion 141, the dimensional consistency of different display panels 100 in the direction X parallel to the plane where the light transmission-covering layer 130 is disposed is improved. This facilitates the design of the display module 10 and the splicing combination of the display panels 100.

It should be noted that the display module disclosed herein may only include a structure where different regions of the same light-transmitting portion have different thicknesses as described in the above embodiment. Alternatively, the display module may only include a structure where different display panels have different thicknesses of the light-transmitting portions as described in the above embodiment. Alternatively, the display module may include both a structure where different regions of the same light-transmitting portion have different thicknesses and a structure where different display panels have different thicknesses of the light-transmitting portions. The specific structure(s) included therein is not limited in the present disclosure. In the embodiments of the present disclosure, whenever discussing the thickness of the light-transmitting portion, the thickness is a thickness of the light-transmitting portion in the light-emitting direction of the display panel. In some embodiments, in the display module disclosed herein, at least part or all of the display panels have the same size, and among these display panels with the same size, the thickness of each region of the light-transmitting portion in a display panel is the same, and the thickness of the light-transmitting portions of different display panels is also the same. This helps improve the display performance of the display module, facilitates the uniform preparation of the display panel, and facilitates the splicing and fixing design of different display panels.

In some embodiments, in order to improve the consistency of the light-transmitting portion guiding the light emission from the side surface of the light transmission-covering layer, the degree of inclination of the first side surface disclosed herein can also be set differently with reference to a distance between a light-emitting element and the light-transmitting portion. In some embodiments, the light-emitting functional layer includes a plurality of light-emitting elements, where the plurality of light-emitting elements include a first light-emitting element adjacent to the edge of the substrate. The distance from at least part of the first light-emitting element to the light-transmitting portion is inversely proportional to the degree of inclination of the first side surface corresponding to the first light-emitting element. In other words, the distance from at least part of the first light-emitting element to the light-transmitting portion is proportional to the corresponding inclination angle of the first side surface corresponding to the first light-emitting element. The distances from different first light-emitting elements to the light-transmitting portion can be the distances from different first light-emitting elements to the light-transmitting portion in a same display panel. Alternatively, the distances from the different first light-emitting elements to the light-transmitting portion can also be the distances from the first light-emitting elements to the corresponding light-transmitting portions in different display panels. Regardless of the interpretation of the different distances, the rule that the distance from the first light-emitting element to the adjacent light-transmitting portion is inversely proportional to the degree of inclination of the first side surface corresponding to the first light-emitting element is to be satisfied.

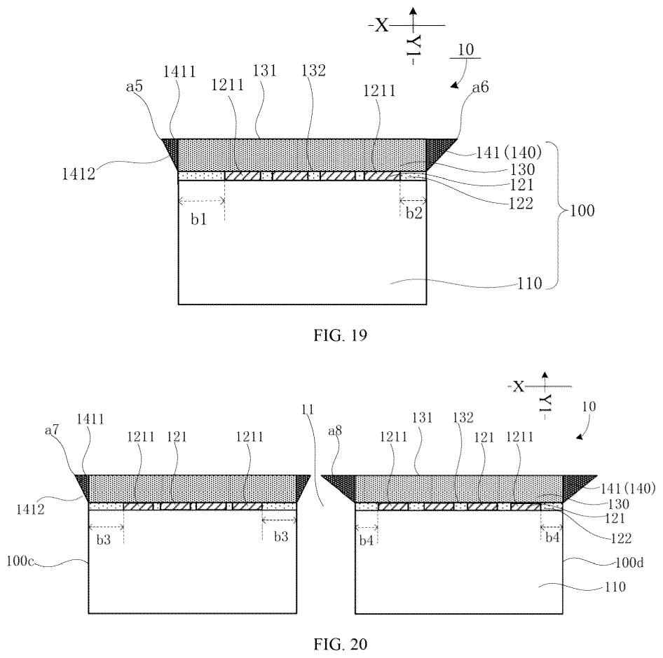

FIG. 19 illustrates a schematic structural diagram of another display module, in accordance with an embodiment of the present disclosure. In the illustrated embodiment, the light-emitting functional layer includes a plurality of light-emitting elements 121. In addition, the light-emitting functional layer also includes a filling layer 122 arranged around the light-emitting elements 121. The light transmission-covering layer 130 covers the light-emitting elements 121 and the filling layer 122 from a side away from the substrate 110. The multiple light-emitting elements 121 include a first light-emitting element 1211 adjacent to the edge of the substrate. The light-transmitting portion 141 includes a first sub-light-transmitting portion 141a and a second sub-light-transmitting portion 141b. A distance b1 between the first sub-light-transmitting portion 141a and an adjacent first light-emitting element 1211 is greater than a distance b2 between the second sub-light-transmitting portion 141b and an adjacent first light-emitting element 1211. The degree of inclination of the first side surface 1412 of the first sub-light-transmitting portion 141a is less than the degree of inclination of the first side surface 1412 of the second sub-light-transmitting portion 141b. In other words, a corresponding inclination angle a5 of the first side surface 1412 of the first sub-light-transmitting portion 141a is greater than a corresponding inclination angle a6 of the first side surface 1412 of the second sub-light-transmitting portion 141b. It can be seen that the distance b1 between the first sub-light-transmitting portion 141a and the adjacent first light-emitting element 1211 is relatively large, so the light emitted from the first light-emitting element 1211 to the side surface of the light transmission-covering layer 130 corresponding to the first sub-light-transmitting portion 141a tends to be in the direction X parallel to the plane where the light transmission-covering layer 130 is disposed. The distance b2 between the second sub-light-transmitting portion 141b and the adjacent first light-emitting element 1211 is relatively small, so the light emitted from the first light-emitting element 1211 to the side surface of the light transmission-covering layer 130 corresponding to the second sub-light-transmitting portion 141b tends to be parallel to the light-emitting direction Y1 of the display panel 100. Accordingly, by setting the degree of inclination of the first side surface 1412 of the first sub-light-transmitting portion 141a to be smaller than the degree of inclination of the first side surface 1412 of the second sub-light-transmitting portion 141b, the first side surface 1412 of the first sub-light-transmitting portion 141a guides the light, to a direction X parallel to the plane where the light transmission-covering layer 130 is disposed, to a smaller extent. The first side surface 1412 of the second sub-light-transmitting portion 141b guides the light, to a direction X parallel to the plane where the light transmission-covering layer 130 is disposed, to a greater extent. This ultimately improves the consistency of guiding the light emitted from the side surface of the light transmission-covering layer by different regions of the light-transmitting portion, which improves the display performance of the display module 10. It should be noted that when a sub-light-transmitting portion disclosed herein is adjacent to a first light-emitting element, the distance between the sub-light-transmitting portion and the first light-emitting element is the distance between the two. When the sub-light-transmitting portion is adjacent to multiple first light-emitting elements, the distance between the sub-light-transmitting portion and the first light-emitting element can be the minimum distance among the distances between the light-transmitting portion and all adjacent first light-emitting elements, or can be the average distance between the sub-light-transmitting portion and all adjacent first light-emitting elements, which is not limited in the present disclosure.

FIG. 20 illustrates a schematic structural diagram of another display panel, in accordance with an embodiment of the present disclosure. In the illustrated embodiment, the light-emitting functional layer disclosed herein includes a plurality of light-emitting elements 121. In addition, the light-emitting functional layer also includes a filling layer 122 disposed around the light-emitting elements 121. The light transmission-covering layer 130 covers the light-emitting elements 121 and the filling layer 122 from the side away from the substrate 110. The multiple light-emitting elements 121 include a first light-emitting element 1211 adjacent to the edge of the substrate. The display module 10 includes at least two display panels, and the at least two display panels include a first display panel 100c and a second display panel 100d. A distance b3 between at least a portion of the light-transmitting portion 141 and an adjacent first light-emitting element 1211 in the first display panel 100c is greater than a distance b4 between at least a portion of the light-transmitting portion 141 and an adjacent first light-emitting element 1211 in the second display panel 100d. The degree of inclination of the first side surface 1412 of the at least portion of the light-transmitting portion 141 in the first display panel 100c is less than the degree of inclination of the first side surface 1412 of the at least portion of the light-transmitting portion 141 in the second display panel 100d. In other words, the inclination angle a7 corresponding to the first side surface 1412 of the at least portion of the light-transmitting portion 141 in the first display panel 100c is greater than the inclination angle a8 of the first side surface 1412 of the at least portion of the light-transmitting portion 141 in the second display panel 100d. Accordingly, the consistency of guiding the light emitted from the side surface of the light transmission-covering layer by different areas of the light-transmitting portion is improved, and the display performance of the display module 10 is improved. It should be noted that when at least part of the light-transmitting portion in the display panel disclosed herein is adjacent to a first light-emitting element, the distance between the at least part of the light-transmitting portion and that first light-emitting element is the distance between the two. When at least part of the light-transmitting portion of the display panel is adjacent to multiple first light-emitting elements, the distance between the at least part of the light-transmitting portion and the first light-emitting element can be the minimum distance among distances between the at least part of the light-transmitting portion and all the adjacent first light-emitting elements, or can be the average value of the distances between the at least part of the light-transmitting portion and all the adjacent first light-emitting elements, which is not limited in the present disclosure.

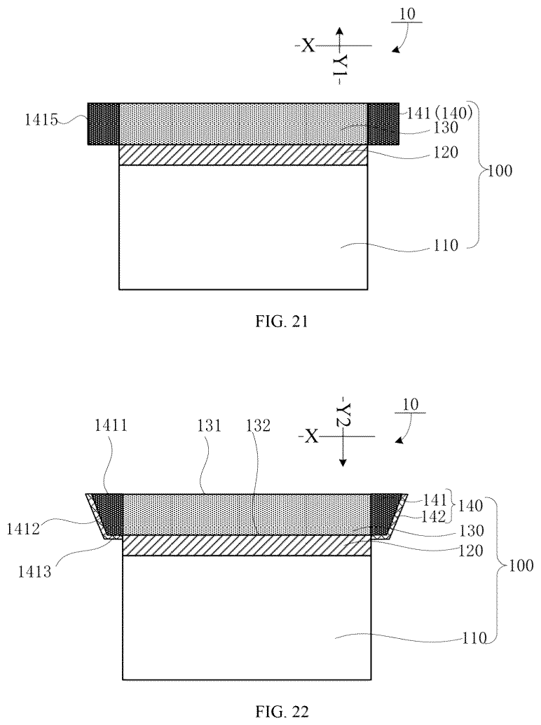

It should be noted that the display module disclosed herein may only include a structure where different areas of the same light-transmitting portion have different distances with adjacent first light-emitting elements. Alternatively, the display module may only include a structure where at least part of the light-transmitting portions of different display panels have different distances with adjacent first light-emitting elements. Alternatively, the display module may include both a structure where different areas of the same light-transmitting portion have different distances with adjacent first light-emitting elements, and a structure where at least part of the light-transmitting portions of different display panels have different distances with adjacent first light-emitting elements. The specific structure included therein is not limited in the present disclosure. In some embodiments, the filling layer disclosed herein may be a black filling layer, such as a black glue layer, thereby achieving a blackening treatment of the substrate and improving the display contrast. In some embodiments, in the display module disclosed herein, the distance between the light-transmitting portion and the first light-emitting element in at least part or all of the display panels is consistent. In these display panels, the distances from different areas of the light-transmitting portion of each display panel to the adjacent first light-emitting elements are the same, and the distances from the light-transmitting portions in different display panels to the adjacent first light-emitting elements are the same. This improves the display performance of the display module, facilitates the uniform preparation of display panels, and facilitates the splicing and fixing design of different display panels. When the side surface of the light-transmitting portion provided by the embodiments of the present disclosure includes an inclined surface, it is not limited to the shape of the light-transmitting portion provided by the above embodiments. In some embodiments, the light-transmitting portion can also be other shapes, as long as it can guide the light emitted from the side surface of the light transmission-covering layer to propagate in a direction parallel to the plane where the light transmission-covering layer is disposed. In addition, the side surface of the light-transmitting portion disclosed herein can also include a surface parallel to the light-emitting direction of the display panel. Refer to FIG. 21, in a schematic structural diagram of another display module disclosed herein, the light-transmitting portion 141 includes a side surface 1415 facing away from the side of the light transmission-covering layer 130. The side surface 1415 of the light-transmitting portion 141 is parallel to the light-emitting direction Y1 of the display panel 100, and the light-transmitting portion 141 can also guide the light emitted from the side surface of the light transmission-covering layer 130 to propagate along the original transmission path of the light inside the light-transmitting portion 141. This helps deal with a situation in which the light at the edge area of the light transmission-covering layer 130 is concentrated and thus tends to propagate along a direction parallel to the light-emitting direction Y1 of the display panel 100, thereby improving the display performance of the display module 10.

FIG. 22 illustrates a schematic structural diagram of another display module, in accordance with an embodiment of the present disclosure. In the illustrated embodiment, the auxiliary structure 140 further includes a light-absorbing layer 142. The light-transmitting portion 141 includes a side surface facing away from the light transmission-covering layer 130, where the light-absorbing layer 142 at least covers at least a portion of the side surface of the light-transmitting portion 141. In some embodiments, the light-absorbing layer 142 disclosed herein covers all exposed surfaces of the light-transmitting portion 142 except the top surface 1411. For example, when the light-transmitting portion 141 includes a first side surface 1412 and a bottom surface 1413, the light-absorbing layer 142 covers the first side surface 1412 and the bottom surface 1413. The light-absorbing layer 142 exposes the top surface 1411 of the light-transmitting portion 141. In the embodiments of the present disclosure, by configuring a light-absorbing layer 142, when adjacent display panels 100 are spliced, if there is a problem of splicing height difference in the light-emitting direction Y1 of the display panel 100, the light-absorbing layer 142 can absorb the side light emitted by an adjacent display panel 100. This can prevent the occurrence of side light leakage of the adjacent display panel 100, thereby improving the display performance of the display module 10. In some embodiments, the light-absorbing layer disclosed herein can be a black light-absorbing structure. Specifically, the light-absorbing layer disclosed herein can be a light-absorbing film, such as a light-absorbing ink film, etc. Alternatively, the light-absorbing layer disclosed herein can also be a carbonized surface of the light-transmitting portion, which is not specifically limited in the present disclosure.

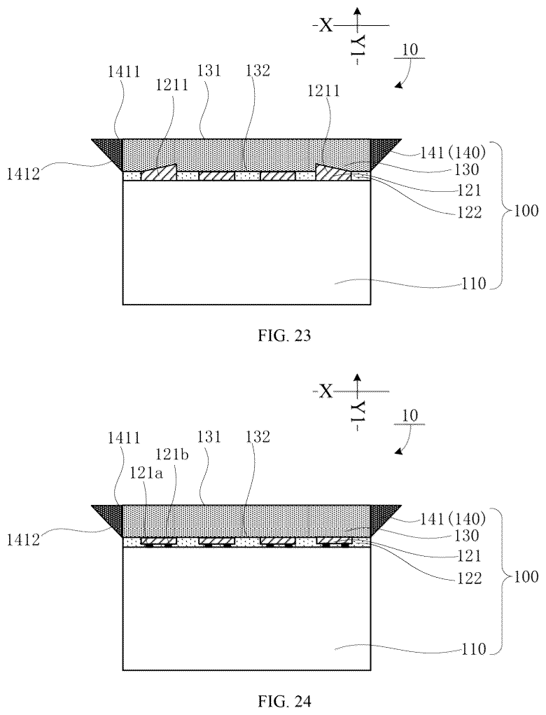

In the display panel disclosed herein, the bright line problem that occurs when the display module displays an image can be solved by optimizing the auxiliary structure to guide the light. In addition, the embodiments of the present disclosure can also help solve the bright line problem, that occurs when the display module displays an image, by improving the angle of the light-emitting surface of the light-emitting element. Referring to FIG. 23, in a schematic structural diagram of another light-emitting element disclosed herein, the light-emitting functional layer includes a plurality of light-emitting elements 121. The light-emitting elements 121 includes a first light-emitting element 1211 adjacent to the edge of the substrate 110, where the light-emitting surface of the first light-emitting element 1211 is inclined toward the side of the auxiliary structure 140 adjacent to the first light-emitting element. The light emitted by the first light-emitting element 1211 tends to propagate in a direction X parallel to the plane where the light transmission-covering layer 130 is disposed, thereby making the light emitted from the side surface of the light transmission-covering layer 130 more inclined towards the direction X parallel to the plane where the light transmission-covering layer 130 is disposed. This then solves the problem from the light-emitting source aspect, where the problem refers to the light emitted from the side surface of the light transmission-covering layer 130 concentrated in a direction Y1 parallel to the light-emitting direction of the display panel 100. This approach also allows to achieve the objective of solving the bright line problem that occurs when the display module 10 displays an image. In some embodiments, in order to achieve the inclined configuration of the light-emitting surface of the first light-emitting element 1211, a special shape can be prepared during the production of the first light-emitting element 1211. Alternatively, a pad is disposed on the side of the first light-emitting element 1211 facing the substrate 110, where the first light-emitting element 1211 is tilted by the pad, thereby achieving the configuration of the inclined light-emitting surface of the first light-emitting element 1211.

In the above embodiments of the present disclosure, the light-emitting element disclosed herein may be a light-emitting diode. FIG. 24 illustrates a schematic structural diagram of another display module, in accordance with an embodiment of the present disclosure. In the illustrated embodiment, the light-emitting element 121 disclosed herein may be a light-emitting diode. The anode 121a and the cathode 121b of the light-emitting diode 121 may both be disposed on the side facing the substrate 110. When the substrate 110 is a circuit board, the anode 121a and the cathode 121b may be in contact and electrically connected with the connection pins (not shown) reserved on the substrate 110. In addition, the light-emitting functional layer disclosed herein may also include a filling layer 122, where the filling layer 122 at least fills the space around the light-emitting elements 121.

In some embodiments, the filling layer 122 may be a black filling layer, such as a black glue layer, to improve the contrast of an image displayed by the display panel. During the preparation process, a black glue layer may be first formed on a substrate (which may be an array substrate). The light-emitting elements 121 may be then pressed at the electrode positions on the corresponding substrate. The light-emitting elements 121 may be pressed to displace the material of the black glue layer at the corresponding connection pins on the substrate 110, so that the light-emitting elements 121 are connected or bonded to the connection pins on the substrate 110.

In some embodiments, the filling layer 122 can be formed on the surface of the substrate 110 facing the light-emitting functional layer. The filling layer 122 is etched to form a groove for setting a light-emitting element. In some embodiments, the groove is also etched to form an electrode hole(s) for the connecting pin(s) of the bare substrate 110. The anode 121a and the cathode 121b can be connected to the connecting pin(s) through their respective corresponding electrode holes. The present disclosure does not limit the way how the filling layer is formed.

In some embodiments, the light-emitting element disclosed herein may be a micro light-emitting diode element, such as a mini light-emitting diode or a micro light-emitting diode. In some embodiments, the light-emitting element disclosed herein may be an organic light-emitting diode element, and the substrate may be an array substrate that provides a driving signal for the organic light-emitting diode element. The present disclosure does not limit the specific types of light-emitting elements disclosed herein. It should be noted that the light-emitting element disclosed herein may include at least a red light-emitting element, a green light-emitting element, and a blue light-emitting element. When the pixels in the light-emitting functional layer include a red light-emitting element, a green light-emitting element, and a blue light-emitting element, the three light-emitting elements may be arranged in a straight line along the row direction or along the column direction, or may be arranged in a staggered arrangement in a herringbone shape, which is not limited in the present disclosure. In some embodiments, the space around the light-emitting elements disclosed herein may not be provided with a filling layer, but may be covered by a light transmission-covering layer, which is not limited in the present. The exact configuration may be determined according to actual needs.

Based on a similar inventive concept, the embodiments of the present disclosure also provide a display device. The display device includes a display module provided by any of the above embodiments. In some embodiments, the display device provided by the embodiments of the present disclosure can be a large-size display device, or a small-size display device such as a mobile terminal, a tablet computer, a wearable device, and the like, which is not limited in the present disclosure.

By means of the above described technical scheme, in the display module and the display device disclosed herein, the display module includes at least one display panel, and the display panel includes an auxiliary structure disposed at the edge of the light transmission-covering layer. The auxiliary structure is configured to optimize and guide the light emitted from the edge of the light transmission-covering layer, so that the light emitted from the edge of the light transmission-covering layer tends to be transmitted in a direction parallel to the plane where the light transmission-covering layer is disposed. This helps solve the problem in existing spliced display screens where the light emitted from the edge of the light transmission-covering layer is more concentrated in the light-emitting direction of a display panel, thereby helping solve the bright line problem on the edge of a display panel when displaying an image. This also helps solve the bright line problem due to the high brightness at the splicing gap between adjacent display panels that are spliced, thereby eventually improving the display performance of the display device.

In the description of the present disclosure, it should be noted that the orientation or position relationship indicated by terms such as “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and the like are based on the orientation or position relationship shown in the drawings, and are only for the convenience of describing the present disclosure and simplifying the description, but do not indicate or imply that the device or element referred to must have a specific orientation, be constructed and operated in a specific orientation, and therefore cannot be understood as limiting the present disclosure.

In addition, the terms “first” and “second” are used for descriptive purposes only and should not be understood as indicating or implying relative importance or implicitly indicating the number of the indicated technical features. Accordingly, the features defined as “first” and “second” may explicitly or implicitly include at least one of the features. In the description of the present disclosure, the meaning of “plurality” is at least two, such as two, three, etc., unless otherwise clearly and specifically defined.

In the present disclosure, unless otherwise clearly specified and limited, the terms “installed”, “connected”, “attached”, “fixed” and the like should be understood in a broad sense. For example, it can be fixedly connected, detachably connected, or integrated; it can be mechanically connected, electrically connected, or able to communicate with each other; or it can be directly connected, or indirectly connected through an intermediate medium; or it can be the internal connection of two elements or the interaction relationship between two elements, unless otherwise clearly defined. For an ordinary person skilled in this field, the specific meanings of the above terms in the present disclosure can be understood according to specific circumstances.

In the present disclosure, unless otherwise clearly specified and limited, a first feature being “above” or “below” a second feature may mean that the first and second features are in direct contact, or the first and second features are in indirect contact through an intermediate medium. Moreover, a first feature being “above”, “up” or “higher than” a second feature may mean that the first feature is directly above or obliquely above the second feature, or simply means that the first feature is higher in level than the second feature. A first feature being “below”, “under” or “lower than” a second feature may mean that the first feature is directly below or obliquely below the second feature, or simply means that the first feature is lower in level than the second feature.

In the present disclosure, the terms “one embodiment”, “some embodiments”, “example”, “specific example”, or “some examples” etc., mean that the specific features, structures, materials, or characteristics described in conjunction with the embodiment or example are included in at least one embodiment or example of the present disclosure. In the specification, the schematic representations of the above terms do not necessarily refer to the same embodiment or example. Moreover, the specific features, structures, materials, or characteristics described may be combined in any one or more embodiments or examples in a suitable manner. In addition, those skilled in the art may combine and integrate different embodiments or examples described in this specification and the features of different embodiments or examples, without contradiction.

Although the embodiments of the present disclosure have been illustrated and described above, it is to be understood that the above embodiments are exemplary and are not to be construed as limitations of the present disclosure. A person skilled in the art may change, modify, replace, and/or change the above embodiments within the scope of the present disclosure.

What is claimed is:

1. A display module, comprising at least one display panel, and the display panel comprising:
a substrate;
a light-emitting functional layer, wherein the light-emitting functional layer is disposed on one side of the substrate;
a light transmission-covering layer, wherein the light transmission-covering layer is disposed on a side of the light-emitting functional layer away from the substrate; and
an auxiliary structure, wherein the auxiliary structure is disposed at an edge of the light transmission-covering layer.

2. The display module according to claim 1, wherein the auxiliary structure extends beyond an edge of the substrate in a direction parallel to a plane where the light transmission-covering layer is disposed.

3. The display module according to claim 1, wherein the display module includes at least two display panels, the at least two display panels are fixedly spliced, and there is a splicing gap between light transmission-covering layers of two adjacent display panels; and
at least a portion of an auxiliary structure of an adjacent display panel is disposed at the splicing gap.

4. The display module according to claim 3, wherein auxiliary structures of the two adjacent display panels are in contact with each other; and
on a reference plane parallel to a plane where the light transmission-covering layer is disposed, orthographic projections of the auxiliary structures of the two adjacent display panels cover an orthographic projection of the splicing gap.

5. The display module according to claim 1, wherein the auxiliary structure includes a light-transmitting portion connected to a side surface of the light transmission-covering layer.

6. The display module according to claim 5, wherein the light-transmitting portion includes a top surface on a side of a light-emitting direction of the display panel, and the light transmission-covering layer includes a top surface on a side away from the substrate; and
the top surface of the light-transmitting portion is flush with the top surface of the light transmission-covering layer.

7. The display module according to claim 5, wherein the light-transmitting portion includes a side surface facing away from the light transmission-covering layer; and
the side surface of the light-transmitting portion includes a first side surface, and along a light-emitting direction of the display panel, the first side surface is inclined toward a side away from the light transmission-covering layer.

8. The display module according to claim 7, wherein a bottom edge of the first side surface facing the substrate is disposed on a connecting part between the light-transmitting portion and the light transmission-covering layer; or
the light-transmitting portion includes a bottom surface on a side opposite to the light-emitting direction of the display panel, and the bottom surface of the light-transmitting portion is connected to the first side surface.

9. The display module according to claim 7, wherein, on a reference plane parallel to a plane where the light transmission-covering layer is disposed, an orthographic projection of the bottom edge of the first side surface facing the substrate overlaps with an orthographic projection of the substrate.

10. The display module according to claim 7, wherein the side surface of the light-transmitting portion further includes a second side surface, and in the light-emitting direction of the display panel, the second side surface is disposed on a side of the first side surface away from the substrate, Wherein, along the light-emitting direction of the display panel, the second side surface is inclined toward a side away from the light transmission-covering layer, or the second side surface is parallel to the light-emitting direction of the display panel.

11. The display module according to claim 7, wherein the first side surface is an inclined plane; or
the first side surface is an inner concave surface that is recessed toward one side of the light transmission-covering layer.

12. The display module according to claim 7, wherein, in a cross-section parallel to the light-emitting direction of the display panel and perpendicular to an edge of the light transmission-covering layer adjacent to the light-transmitting portion, an inclination angle between a line connecting two end points of the first side surface and a plane where a top surface of the light transmission-covering layer is disposed is between 60-85 degrees.

13. The display module according to claim 7, wherein a thickness of at least a part of the light-transmitting portion in the light-emitting direction of the display panel is inversely proportional to a degree of inclination of a first side surface corresponding to the part of the light-transmitting portion.

14. The display module according to claim 7, wherein the light-transmitting portion includes a first sub-light-transmitting portion and a second sub-light-transmitting portion, a thickness of the first sub-light-transmitting portion in the light-emitting direction of the display panel is greater than a thickness of the second sub-light-transmitting portion in the light-emitting direction of the display panel, and a degree of inclination of a first side surface of the first sub-light-transmitting portion is less than a degree of inclination of a first side surface of the second sub-light-transmitting portion; or
the display module includes at least two display panels, the at least two display panels include a first display panel and a second display panel, a thickness of at least a portion of a light-transmitting portion of the first display panel is greater than a thickness of at least a portion of a light-transmitting portion of the second display panel, wherein a degree of inclination of a first side surface of the at least portion of the light-transmitting portion of the first display panel is less than a degree of inclination of a first side surface of the at least portion of the light-transmitting portion of the second display panel.

15. The display module according to claim 7, wherein the light-emitting functional layer includes a plurality of light-emitting elements, and the plurality of light-emitting elements include a first light-emitting element adjacent to an edge of the substrate; and
a distance from at least a portion of the first light-emitting element to the light-transmitting portion is inversely proportional to a degree of inclination of a first side surface corresponding to the first light-emitting element.

16. The display module according to claim 7, wherein the light-emitting functional layer includes a plurality of light-emitting elements, and the plurality of light-emitting elements include a first light-emitting element adjacent to an edge of the substrate, wherein:
the light-transmitting portion includes a first sub-light-transmitting portion and a second sub-light-transmitting portion, wherein a distance between the first sub-light-transmitting portion and a corresponding adjacent first light-emitting element is greater than a distance between the second sub-light-transmitting portion and a corresponding adjacent first light-emitting element, wherein a degree of inclination of a first side surface of the first sub-light-transmitting portion is less than a degree of inclination of a first side surface of the second sub-light-transmitting portion; or
the display module includes at least two display panels, the at least two display panels include a first display panel and a second display panel, a distance between at least a portion of a light-transmitting portion in the first display panel and a corresponding adjacent first light-emitting element is greater than a distance between at least a portion of a light-transmitting portion in the second display panel and a corresponding adjacent first light-emitting element, wherein an degree of inclination of a first side surface of the at least portion of the light-transmitting portion in the first display panel is less than an degree of inclination of a first side surface of the at least portion of the light-transmitting portion in the second display panel.

17. The display module according to claim 5, wherein the light-transmitting portion includes a side surface facing away from the light transmission-covering layer; and
the side surface of the light-transmitting portion is parallel to a light-emitting direction of the display panel.

18. The display module according to claim 5, wherein the auxiliary structure further includes a light-absorbing layer; and
the light-transmitting portion includes a side surface facing away from the light transmission-covering layer, wherein the light-absorbing layer at least covers at least a portion of the side surface of the light-transmitting portion.

19. The display module according to claim 18, wherein the light-absorbing layer is a light-absorbing film; or
the light-absorbing layer is a carbonized surface of the light transmitting portion.

20. The display module according to claim 5, wherein the light-transmitting portion and the light transmission-covering layer form an integral continuous structure.

21. The display module according to claim 1, wherein the light-emitting functional layer includes a plurality of light-emitting elements, the light-emitting elements include a first light-emitting element adjacent to an edge of the substrate, and a light-emitting surface of the first light-emitting element is inclined toward the auxiliary structure.

22. A display device, comprising a display module, wherein the display module includes at least one display panel, and the display panel includes:
a substrate;
a light-emitting functional layer, wherein the light-emitting functional layer is disposed on one side of the substrate;
a light transmission-covering layer, wherein the light transmission-covering layer is disposed on a side of the light-emitting functional layer away from the substrate; and
an auxiliary structure, wherein the auxiliary structure is disposed at an edge of the light transmission-covering layer.
